(19) United States
(12) Patent Application Publication
(10) Pub. No.: US 2026/0036913 A1
(43) Pub. Date: Feb. 5, 2026

(54) EXTREME ULTRAVIOLET LITHOGRAPHY DEVICE AND OPERATING METHOD THEREOF

(71) Applicant: Samsung Electronics Co., Ltd., Suwon-si (KR)

(72) Inventors: Dahae Lee, Suwon-si (KR); Iksun Park, Suwon-si (KR); Dongwook Kim, Suwon-si (KR); Jeonggil Kim, Suwon-si (KR); Seulgi Lee, Suwon-si (KR); Eunhee Jeang, Suwon-si (KR); Keon Huh, Suwon-si (KR)

(21) Appl. No.: 19/203,306

(22) Filed: May 9, 2025

(30) Foreign Application Priority Data
Aug. 5, 2024 (KR) 10-2024-0103979

(51) Int. Cl. G03F 7/00; G03F 1/22

(52) U.S. Cl. CPC G03F 7/70504; G03F 1/22; G03F 7/70033; G03F 7/70116; G03F 7/70508; G03F 7/706; G03F 7/70975

(57) ABSTRACT

An operating method of an extreme ultraviolet (EUV) lithography device includes obtaining a target image, obtaining position matching information between field facets included in a field facet mirror (FFM) and pupil facets included in a pupil facet mirror (PFM), obtaining information of a pupil intensity of the pupil facets of the PFM, and performing rendering of one or more individually selectable pupil facets of the PFM based on the position matching information, the target image, and the pupil intensity.

### CROSS-REFERENCE TO RELATED APPLICATION

This application is based on and claims priority under 35 U.S.C. § 119 to Korean Patent Application No. 10-2024-0103979, filed on Aug. 5, 2024, in the Korean Intellectual Property Office, the disclosure of which is incorporated by reference herein in its entirety.

### BACKGROUND

The inventive concept relates to an extreme ultraviolet lithography device and an operating method thereof, and more particularly, to a method of performing rendering of a pupil facet mirror by considering a status of equipment included in an extreme ultraviolet lithography device.

In general, as a semiconductor circuit line width becomes finer, a light source having a shorter wavelength may be required. For example, extreme ultraviolet (EUV) light is used as an exposure light source. Due to absorption characteristics of EUV light, a reflective EUV mask is generally used in an EUV exposure process. Also, an illumination optical system for transmitting EUV light to an EUV mask and a projection optical system for projecting EUV light reflected from the EUV mask to an exposure target may each include a plurality of mirrors.

The above information may be provided as a related art for the purpose of helping understanding the inventive concept. Neither claim nor determination is made whether any of the above description may be applied as prior art related to the inventive concept.

### SUMMARY

The inventive concept provides a method of performing rendering of a pupil facet mirror by considering a status of equipment included in an extreme ultraviolet (EUV) lithography device.

The inventive concept provides a method of rendering an optimal pupil facet mirror according to a target image.

Technical objectives to be achieved by the inventive concept are not limited thereto, and other unmentioned technical objectives will be apparent to one of ordinary skill in the art from the description of the inventive concept.

According to an aspect of the inventive concept, an operating method of an extreme ultraviolet (EUV) lithography device includes obtaining a target image, obtaining position matching information between field facets included in a field facet mirror (FFM) and pupil facets included in a pupil facet mirror (PFM), obtaining information of a pupil intensity of the pupil facets of the PFM, and performing rendering of one or more individually selectable pupil facets of the PFM based on the position matching information, the target image, and the pupil intensity.

According to another aspect of the inventive concept, an operating method of an extreme ultraviolet (EUV) lithography device includes obtaining a target image, obtaining position matching information between field facets included in a field facet mirror (FFM) and pupil facets included in a pupil facet mirror (PFM), obtaining aberration information of equipment included in the EUV lithography device, and performing rendering of the PFM based on the position information, the target image, and the aberration information.

According to another aspect of the inventive concept, An operating method of an extreme ultraviolet (EUV) lithography device includes obtaining a target image, obtaining light path information for light output from a field facet mirror (FFM) reaching a pupil facet mirror (PFM), obtaining optical performance information of equipment included in the EUV lithography device, and performing rendering of the PFM corresponding to the target image based on the light path information, the target image, and the optical performance information.

### BRIEF DESCRIPTION OF THE DRAWINGS

Embodiments will be more clearly understood from the following detailed description taken in conjunction with the accompanying drawings in which:

FIG. 1 is a block diagram illustrating an extreme ultraviolet (EUV) lithography device, according to an embodiment;

FIG. 2 is a diagram illustrating an EUV lithography device, according to an embodiment;

FIG. 3 is a diagram illustrating an illuminator of an EUV lithography device, according to an embodiment;

FIG. 4 is a diagram illustrating an example of performing rendering by using a tool provided by an illuminator equipment engineer;

FIG. 5 is a block diagram illustrating a computing device for performing pupil facet mirror (PFM) rendering, according to an embodiment;

FIG. 6 is a diagram for describing a method of performing first rendering, according to an embodiment;

FIG. 7 is a diagram for describing a rendering method considering deterioration of an EUV lithography device, according to an embodiment;

FIG. 8 is a diagram for describing a method of determining whether equipment included in an EUV lithography device has deteriorated based on a pupil intensity, according to an embodiment;

FIG. 9 is a diagram illustrating an example of reflecting a contamination status of a collector when determining a pupil shape, according to an embodiment;

FIGS. 10 to 12 are diagrams for describing a rendering method considering aberration of equipment, according to an embodiment;

FIG. 13 is a flowchart for describing an operating method of an EUV lithography device, according to an embodiment; and

FIG. 14 is a graph illustrating a normalized image log slope (NILS) change according to the number of pupil facet replacements of a PFM, according to an embodiment.

### DETAILED DESCRIPTION OF THE EMBODIMENTS

Hereinafter, embodiments will be described in detail with reference to the attached drawings. When describing with reference to the attached drawings, the same elements are denoted by the same reference numerals even though they are shown in different drawings, and a repeated description thereof will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

In an exposure process, as a wavelength of a light source decreases, a solution may increase, the density of an integrity circuit may increase, diffraction and interference may be reduced or minimized, a process window may be expanded, and a fine structure may be manufactured. A deep ultraviolet (DUV) lithography device generally uses light with a wavelength of 193 nm to 248 nm. However, as the importance of a photo process increases with the miniaturization of a pattern, a DUV lithography device may have limitations in implementing a smaller feature size due to wavelength limitations.

An extreme ultraviolet (EUV) lithography device according to an embodiment may use light with a shorter wavelength (e.g., 13.5 nm) than a wavelength of light used in a DUV lithography device. Accordingly, the EUV lithography device may accurately transfer a finer feature and a more complex pattern than the DUV lithography device. However, the EUV lithography device may have a problem in that its performance deteriorates, compared to the DUV lithography device, due to a limitation in the degree of freedom of a pupil due to a difference in hardware structure (e.g., an illuminator), which is different from that of the DUV lithography device. Due to these characteristics, normalized image log slope (NILS) reduction may occur rapidly due to a change in K1 (a constant representing a resolution in a lithography device). That is, the limitation of the pupil may also affect deterioration of a wafer pattern.

As described below in detail, an operating method of an EUV lithography device according to an embodiment may include performing rendering of a pupil facet mirror (PFM) to prevent deterioration of the performance of the lithography device. In more detail, the operating method of the EUV lithography device may include performing rendering of the PFM by considering a status of equipment included in the EUV lithography device.

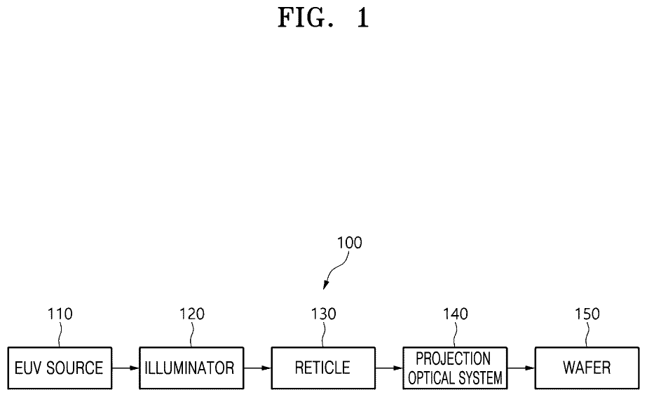

The PFM rendering according to an embodiment may refer to an operation of allocating illumination rays reflected from a field facet mirror (FFM) to appropriate positions of the PFM. A PFM rendering image generated through rendering according to an embodiment may be used to determine EUV patterning performance (e.g., criteria dimension (CD) distribution, dose, and depth of focus (DoF)). Before describing a rendering method according to an embodiment, a structure of an EUV lithography device including a PFM and an FFM will be described with reference to FIGS. 1 to 3.

FIG. 1 is a block diagram illustrating an EUV lithography device, according to an embodiment.

Referring to FIG. 1, an EUV lithography device 100 according to an embodiment may include an EUV source 110, an illuminator 120, a reticle 130, a projection optical system 140, and a wafer 150. However, an internal structure of the EUV lithography device 100 is not limited to that illustrated in FIG. 1. That is, it may be understood by one of ordinary skill in the art related to the present embodiment that some of elements illustrated in FIG. 1 may be omitted or new elements may be further added according to a design of the EUV lithography device 100.

The EUV source 110 according to an embodiment may be implemented to generate and output high-energy-density EUV light within a wavelength range of about 5 nm to about 50 nm. For example, the EUV source 110 may generate and output high-energy-density EUV light with a wavelength of 13.5 nm. The EUV source 110 may be a plasma-based light source or a synchrotron radiation light source. The plasma-based light source refers to a light source that generates plasma and uses light emitted by the plasma. The plasma-based light source may include a laser-produced plasma (LPP) light source or a discharge-produced plasma (DPP) light source. However, the EUV source 110 according to an embodiment is not limited to a plasma-based light source or a synchrotron radiation light source.

The illuminator 120 according to an embodiment may generally uniformly distribute EUV light generated from the EUV source 110 so that the EUV light accurately reaches the reticle 130. It may be very desirable for the EUV light to accurately reach the reticle to ensure that a pattern is uniformly exposed. The illuminator 120 may include an FFM and a PFM. The FFM may include a plurality of field facets, and may disperse EUV light at various angles to create generally uniform illumination. The PFM may include a plurality of pupil facets, and may adjust light to create a specific polarization state or intensity distribution. The illuminator 120 may be referred to as an illumination system or an illumination optical system.

The reticle 130 according to an embodiment may be a photomask including a pattern to be transferred to the wafer 150. When EUV light received through the illuminator 120 passes through or is reflected by the reticle 130, the pattern formed in the reticle 130 may be transferred to the wafer 150. The reticle 130 may be referred to as a mask or a photomask.

The projection optical system 140 according to an embodiment may reduce the pattern of the reticle 130 by using EUV light and project the reduced pattern to the wafer 150. The projection optical system 140 may include a plurality of reflective mirrors (e.g., 6 to 8 reflective mirrors), and each mirror may accurately reflect and reduce light so that the reflected and reduced light reaches the wafer 150. The projection optical system 140 may include a mirror adjustment system that finely adjusts a position and an angle of a mirror to maintain an optimal or desired focus and image.

The wafer 150 according to an embodiment may be covered with a photoresist layer, and the pattern of the reticle 130 may be transferred through EUV light to the photoresist layer. The exposed wafer 150 may form a pattern with a very high resolution by using EUV light with a specific wavelength (e.g., 13.52 nm).

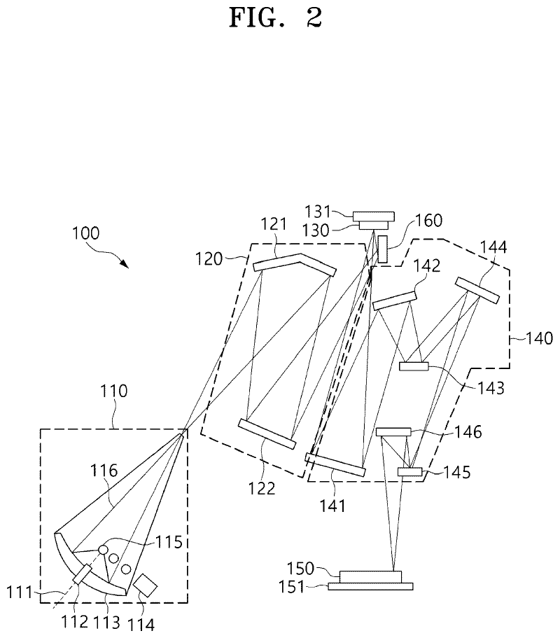

FIG. 2 is a diagram illustrating an EUV lithography device, according to an embodiment. The description made with reference to FIG. 1 may also apply to FIG. 2.

Referring to FIG. 2, the EUV lithography device 100 according to an embodiment may include the EUV source 110, the illuminator 120, the reticle 130, the projection optical system 140, and the wafer 150.

The EUV source 110 according to an embodiment is configured to generate EUV light 116. The EUV source 110 may include a collector 113. The collector 113 may include a curved mirror configured to collect the EUV light 116 generated by the EUV source 110 and focus the EUV light 116 toward an intermediate focus. The EUV light 116 may be generated from plasma generated from droplets 115 of a target material exposed to a laser beam 111 (e.g., droplets of the target material including Sn droplets or other types of droplets). The droplets 115 may be provided across a front surface of the collector 113 by a droplet generator (DG) head 114. The DG head 114 may be pressed to provide a fine and controlled output of the droplets 115.

A laser source, such as a pulsed carbon dioxide (CO2) laser, may generate the laser beam 111. The laser beam 111 may be provided (e.g., by a beam delivery system to a focus lens) so that the laser beam 111 is focused through a window 112 of the collector 113. The laser beam 111 may be focused on the droplets 115 that generate plasma. The plasma may generate plasma emissions, some of which may be the EUV light 116. The laser beam 111 may be pulsed at a timing synchronized with the flow of the droplets 115 from the DG head 114.

The illuminator 120 may include a plurality of reflective mirrors configured to focus and/or direct the EUV light 116 onto the reticle 130. The plurality of mirrors may include, for example, an FFM 121 and a PFM 122. Facets of the FFM 121 and the PFM 122 may be arranged to focus, polarize, and/or otherwise adjust the EUV light 116 from the EUV source 110 to increase uniformity of the EUV light 116 and/or increase specific types of EUV light components (e.g., transverse electric (TE) polarized radiation and transverse magnetic™ polarized radiation). A relay mirror 160 may be included to direct the EUV light 116 from the illuminator 120 onto the reticle 130.

The projection optical system 140 may include a plurality of mirrors configured to project the EUV light 116 onto the wafer 150 after the EUV light 116 is modified based on a pattern of the reticle 130. The plurality of reflective mirrors may include, for example, mirrors 141 to 146. In some implementations, the mirrors 141 to 146 may be configured to focus or reduce the EUV light 116 to an exposure field that may include one or more die areas on the wafer 150.

The EUV lithography device 100 may include a wafer stage 151 (or a substrate stage) configured to support the wafer 150. Furthermore, the wafer stage 151 may be configured to move (or step) the wafer 150 through a plurality of exposure fields when the EUV light 160 transfers the pattern from the reticle 130 to the wafer 150.

The EUV lithography device 100 may also include a reticle stage 131 configured to support and/or fix the reticle 130. Furthermore, the reticle stage 131 may be configured to move or slide the reticle through the EUV light 116 so that the reticle 130 is scanned by the EUV light 116. In this manner, a pattern larger than the beam or field of the EUV light 116 may be transferred to the wafer 150.

In an exposure operation (e.g., an EUV exposure operation), the DG head 114 may provide a stream of droplets 115 across the front surface of the collector 113. The laser beam 111 contacts the droplets 115 to generate plasma. The plasma may emit or generate the EUV light 116. The EUV light 116 may be collected by the collector 113 and directed toward the FFM 121 of the illuminator 120. The FFM 121 reflects the EUV light 116 onto the PFM 122 that reflects the EUV light 116 on the relay mirror 160 toward the reticle 130. The EUV light 116 may be modified by the pattern of the reticle 130. In other words, the EUV light 116 may be reflected from the reticle 130 based on the pattern of the reticle 130. The reticle 130 may direct the EUV light 116 toward the mirror 142 in the projection optical system 140 that reflects the EUV light 116 onto a mirror 134b. The EUV light 116 may be continuously reflected and reduced in the projection optical system 140 by the mirrors 143 to 146. The mirror 146 may reflect the EUV light 116 onto the wafer 15 so that the pattern of the reticle 130 is transferred to the wafer 150. The above exposure operation is an example, and the EUV lithography device 100 may operate according to other EUV techniques and EUV light paths including more mirrors, fewer mirrors, and/or mirrors having different configurations.

As described above, FIG. 2 is provided as an example. Another example may be different from that described with reference to FIG. 2. For example, another example may include additional components, fewer components, different components, or differently arranged components than those illustrated in FIG. 2. Additionally or alternatively, a set of components of FIG. 2 (e.g., one or more components) may perform one or more functions described herein as being performed by another set of components.

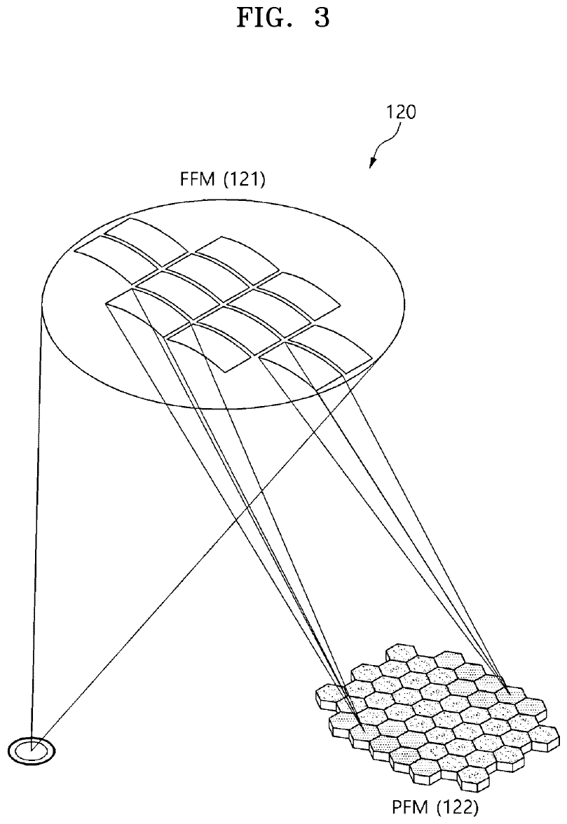

FIG. 3 is a diagram illustrating the illuminator 120 of the EUV lithography device 100, according to an embodiment. The description made with reference to FIGS. 1 and 2 may also apply to FIG. 3.

Referring to FIG. 3, the illuminator 120 may include the FFM 121 and the PFM 122 for forming PFM rendering. The FFM 121 may reflect EUV light (e.g., the EUV light 116) from an EUV source (e.g., the EUV source 110 of FIG. 2) in the form of a slit. Each field facet may deliver light to positions of the PFM 122 including a limited number of pupil facets called an illumination channel group. Each of field facets constituting the FFM 121 may correspond to a plurality of facet fields constituting the PFM 122. For example, illustration channel groups in the EUV lithography device including 336 field facets and 1,520 pupil facets may be implemented with 4 or 5 positions of the PFM 122.

The PFM 122 may form a pupil shape and may transmit the pupil shape to a reticle (e.g., the reticle 130 of FIG. 2). The pupil shape is a collection of light (e.g., EUV light) transmitted from the illuminator 120 to the reticle 130. The pupil shape may represent a path and distribution of light generated and controlled by the illuminator 120 and may play an important role in accurately transferring a pattern by reaching the reticle 130. To transfer the accurate pupil shape to the reticle 130, accurate PFM rendering should be performed first. As described above, PFM rendering is an operation of allocating EUV light reflected from the FFM 121 to an appropriate position of the PFM 122.

The PFM rendering may be performed by inputting a target image to a rendering tool and obtaining a rendering result corresponding to the target image. The target image may be an ideal diffraction image that is most suitable for a user's needs. The diffraction image is a diffraction pattern image of light formed by the reticle, and may include a target pattern to be finally transferred to a wafer. In other embodiments, the target image may be an ideal target pupil shape image that is most suitable for a user's needs.

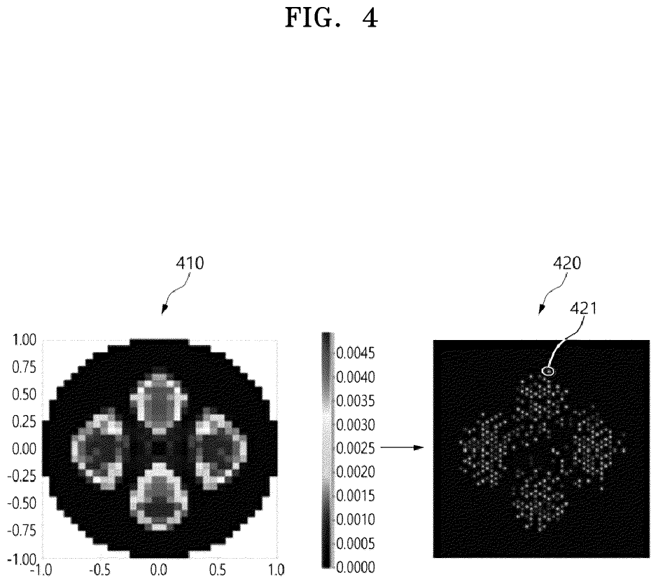

FIG. 4 is a diagram illustrating an example of performing rendering by using a tool provided by an illuminator equipment engineer. The description made with reference to FIGS. 1 to 3 may also apply to FIG. 4.

Referring to FIG. 4, PFM rendering may be automatically performed by using a tool provided by an illuminator (e.g., illuminator 120) equipment engineer (hereinafter, referred to as an equipment engineer). In more detail, when the tool provided by the equipment engineer receives a target image 410, the tool may automatically perform PFM rendering based on the target image 410 and may output a rendering image 420.

When the tool provided by the equipment engineer is used, there may be a limitation in the degree of freedom of a pupil facet because an FFM (e.g., the FFM 121 of FIG. 2) may only be matched to a specific pupil facet position of a PFM (e.g., the PFM 122 of FIG. 2). Furthermore, the tool provided by the equipment engineer has a disadvantage in that rendering is not optimized when determining a pupil shape and thus, a desired pupil facet may not be selected.

When the tool provided by the equipment engineer is used, because an ideal pupil facet of a PFM suitable for the target image 410 may not be selected, a pupil facet 421 at an undesired position may be selected, which may lead to a decrease in image contrast of a wafer.

As the pupil facet 421 at the undesired position is selected, an ideal pupil shape is not generated, and rendering may be repeatedly performed to generate an ideal pupil shape, but there may be a limit to optimization and a limit to optimizing a pattern NILS due to time loss.

When deterioration occurs in equipment of an EUV lithography device, a pupil intensity of a pupil facet may decrease. Deterioration according to an embodiment is a broad concept, which may include performance degradation over time, and may include both contamination due to penetration of an external substance and performance degradation due to a change in an internal substance. For example, a collector (e.g., the collector 113 of FIG. 2), an FFM (e.g., the FFM 121 of FIG. 2), a PFM (e.g., the PFM 122 of FIG. 2), or a projection optical system (e.g., the projection optical system 140 of FIG. 4) may be contaminated by dust, a chemical substance (e.g., a chemical substance used during a process), an organic substance (e.g., a photoresist residue), moisture, or water, or may have an aberration due to physical wear of an optical component or thermal expansion and contraction of an optical component. However, causes of deterioration according to an embodiment are not limited to the above examples.

A pupil intensity according to an embodiment may refer to an intensity of light (e.g., EUV light) in a PFM area. A pupil intensity may play an important role in improving or optimizing an illumination condition, and may determine the uniformity and resolution of pattern transfer. When pupil intensities of pupil facets constituting a PFM are uniform and enhanced or optimized, an EUV lithography device may transfer a pattern with a higher resolution and thus may achieve a smaller feature size. When PFM rendering is performed without considering deterioration of equipment, it may be difficult to select an optimal or desired pupil facet, which may result in poor wafer pattern quality.

As described below in detail, an operating method of an EUV lithography device according to an embodiment may include individually selecting a pupil facet when performing PFM rendering. Furthermore, the operating method of the EUV lithography device may include detecting whether deterioration has occurred in equipment, and generating an optimal or desired pupil shape by reflecting the deterioration of the equipment when performing PFM rendering and by replacing a pupil facet determined to be defective with another pupil facet.

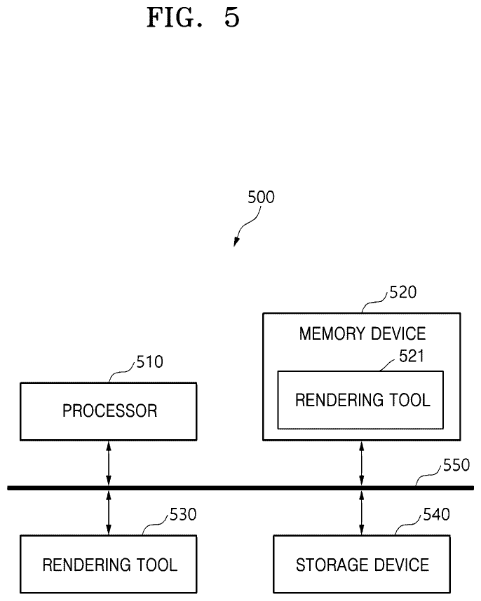

FIG. 5 is a block diagram illustrating a computing device for performing PFM rendering, according to an embodiment. The description made with reference to FIGS. 1 to 4 may also apply to FIG. 5.

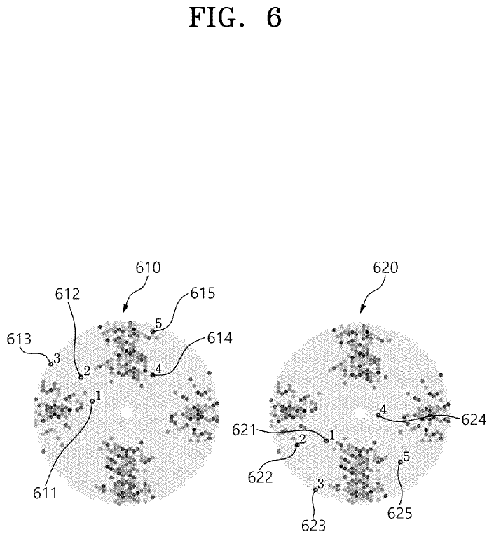

Referring to FIG. 6, a computing device 500 according to an embodiment may include at least one processor 510, a memory device 520, an input/output device 530, and a storage device 540 connected to a system bus 550.

Through the system bus 550, the processor 510, the memory device 520, the input/output device 530, and the storage device 540 may be electrically connected to each other to exchange data. A configuration of the system bus 550 is not limited thereto, and may further include an arbitration means for efficient management.

The processor 510 may be implemented to control an overall operation of the computing device 500. The processor 510 may be implemented to execute at least one instruction. For example, the processor 510 may be implemented to execute software (an application program, an operating system, and/or device drivers) that is stored in the memory device 520. The processor 510 may execute an operating system loaded into the memory device 520. The processor 510 may execute various application programs to be driven based on the operating system. For example, the processor 510 may drive a rendering tool 521 read from the memory device 520. In an embodiment, the processor 510 may be a central processing unit (CPU), a microprocessor, an application processor (AP), or any similar processing device.

The memory device 520 may be implemented to store at least one instruction. For example, an operating system or application programs may be loaded into the memory device 520. When the computing device 500 is booted, an OS image stored in the storage device 540 may be loaded into the memory device 520 based on a booting sequence. All input/output operations of the computing device 500 may be supported by an operating system. Likewise, application programs may be loaded into the memory device 520 to be selected by a user or provide a basic service. In particular, the rendering tool 521 for performing PFM rendering may be loaded from the storage device 540 into the memory device 520.

Also, the memory device 520 may include one or more of a volatile memory, such as dynamic random-access memory (DRAM) or static random-access memory (SRAM), or a nonvolatile memory such as flash memory, phase-change random-access memory (PRAM), resistance random-access memory (RRAM), nano-floating gate memory (NFGM), polymer random-access-memory (PoRAM), magnetic random-access memory (M RAM), or ferroelectric random-access memory (FRAM).

The rendering tool 521 may perform pupil facet rendering by using data measured by an actual EUV lithography device (e.g., the EUV lithography device 100 of FIG. 1), or may perform pupil facet rendering based on simulation data corresponding to the actual EUV lithography device (e.g., the EUV lithography device 100 of FIG. 1).

The rendering tool 521 may obtain a target image. For example, the rendering tool 521 may obtain a target image by using a source mask optimization (SMO) method.

The rendering tool 521 may obtain position matching information between field facets included in an FFM (e.g., the FFM 121 of FIG. 2) and pupil facets included in a PFM (e.g., the PFM 122 of FIG. 2). The position matching information according to an embodiment may refer to information about a position of a facet mirror that light output from a field facet included in the FFM may reach. That is, the position matching information may include light path information for light output from the FFM that reaches the PFM. The position matching information may be expressed as a coordinate pair of a pupil facet matching a field facet. For example, when an iₜₕ field facet of the FFM including n (n is a natural number) field facets and a j^{th} pupil facet of the PFM including m pupil facets match each other, position matching information between the iₜₕ field facet and the j^{th} pupil facet may be expressed as (iₜₕ_field facet, j^{th}-pupil facet). The rendering tool 521 may obtain position matching information between field facets and pupil facets through linear programming and priority optimization. In other embodiments, the rendering tool 521 may obtain position matching information based on an illumination file of equipment. The illumination file may include data related to illumination settings of an exposure process. The illumination file may include information about positions and numbers of the FFM and the PFM. The rendering tool 521 may obtain position coordinates and identification numbers of the FFM and the PFM based on the illumination file. The rendering tool 521 may match a position of the FFM to a position of the PFM that light reflected from the position of the FFM reaches, based on the illumination file. The rendering tool 521 may detect which pupil facet a specific field facet transmits light to and which field facet a specific pupil facet receives light from. However, a method of obtaining position matching information is not limited to the above example.

The rendering tool 521 may obtain optical performance information of the equipment included in the EUV lithography device. For example, the rendering tool 521 may obtain pupil intensity information of pupil facets included in the PFM. In other embodiments, the rendering tool 521 may obtain aberration information of the equipment (e.g., projection optical system) included in the EUV lithography device.

The optical performance information may be data actually measured in the EUV lithography device 100 by using a measurement device. The measurement device may include any of various high-resolution optical measurement devices, such as a Shack-Hartmann wavefront sensor, a phase-shifting interferometer, a photodiode array, a CCD/CMOS image sensor, or a reflectometer capable of measuring a pupil intensity. Also, the measurement device may include a wavefront sensor or an interferometer for measuring aberration. However, the measurement device is not limited to the above examples, and may include various devices capable of measuring optical performance. The EUV lithography device 100 may include the measurement device, or the measurement device may be implemented as a device separate from the EUV lithography device 100.

The optical performance information may be data obtained through simulation, rather than data actually measured by using the measurement device. The rendering tool 521 may perform rendering based on data (e.g., a pupil intensity or aberration) obtained through simulation. In other embodiments, the rendering tool 521 may perform rendering by using both actually measured data and data obtained through simulation. For example, the rendering tool 521 may perform initial rendering and optimization through a pupil intensity obtained through simulation, and may verify and correct a rendered result through a pupil intensity measured by the actual EUV lithography device 100.

The rendering tool 521 may perform PFM rendering based on the position matching information, the target image, and the pupil intensity. The rendering tool 521 may perform rendering of selecting active pupil facets corresponding to the target image, based on the position matching information. The active pupil facet may refer to a pupil facet selected through rendering from all pupil facets included in the PFM. A rendering operation comprising selecting active pupil facets corresponding to the target image may be referred to as a first rendering. Because the rendering tool 521 obtains the position matching information, the rendering tool 521 may select an individual pupil facet according to the target image.

FIG. 6 is a diagram for describing a method of performing first rendering, according to an embodiment. The description made with reference to FIGS. 1 to 5 may also apply to FIG. 6.

Referring to FIG. 6, in an FFM including n (n is a natural number) field facets, according to position matching information 610 of an iₜₕ (i is a natural number equal to or less than n) field facet, the iₜₕ field facet may select pupil facets 611 to 615, and according to position matching information 620 of a j^{th} (j is a natural number different from i and equal to or less than n) field facet, the j^{th} field facet may select pupil facets 621 to 625.

A rendering tool (e.g., the rendering tool 521 of FIG. 5) may select an individual pupil facet suitable for a target image based on position matching information. For example, the rendering tool may select the pupil facet 614 based on the position matching information 610 of the iₜₕ field facet, and may select the pupil facet 612 based on the position matching information 620 of the j^{th} field facet. Thus, according to some embodiments, pupil facets may be individually selectable from among a plurality of pupil facts.

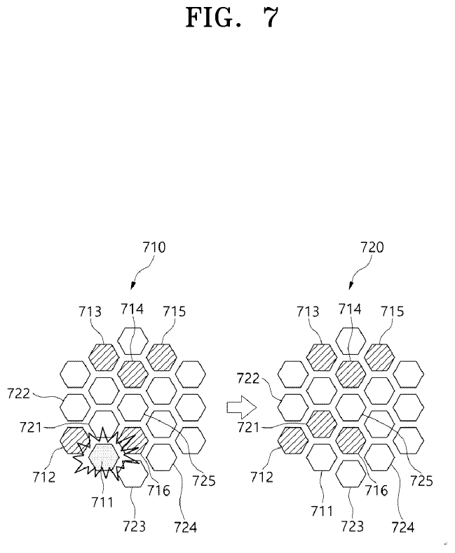

Referring back to FIG. 5, the rendering tool 521 may detect a deteriorated pupil facet whose pupil intensity is less than a threshold value from among active pupil facets. For example, the rendering tool 521 may detect a pupil facet whose pupil intensity has fallen below 50% as a deteriorated pupil facet, i.e., the pupil intensity does not satisfy a defined threshold value. However, a method of determining a threshold value for detecting a deteriorated pupil facet is not limited to the above example. The rendering tool 521 may perform a rendering operation comprising selecting a changed pupil facet to replace the deteriorated pupil facet, based on the position matching information, the target image, and the pupil intensity. The rendering tool 521 may perform rendering to generate an optimal or desired pupil shape by replacing the deteriorated pupil facet determined to be defective with another pupil facet, which reflects deterioration of the equipment. The pupil facet selected instead of the deteriorated pupil facet may be referred to as a changed pupil facet. Hereinafter, a rendering method of selecting a changed pupil facet to replace a deteriorated pupil facet will be described in detail with reference to FIGS. 7 to 9.

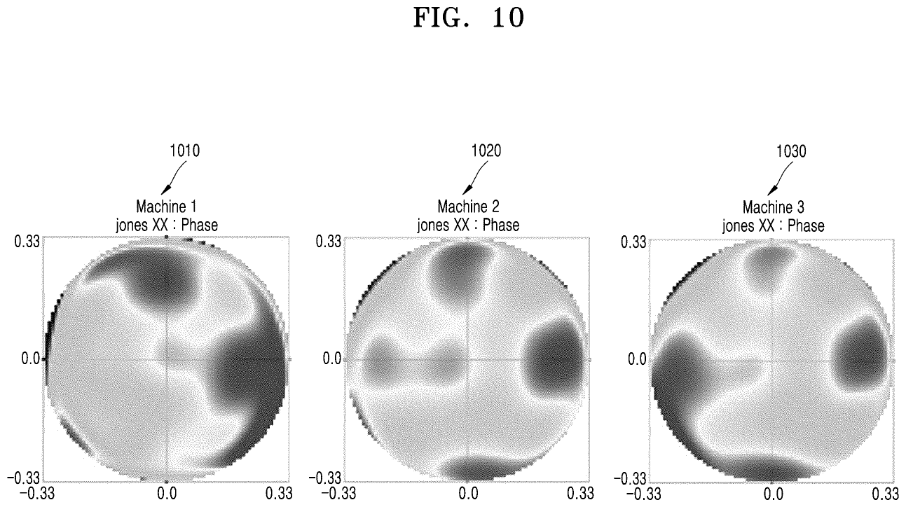

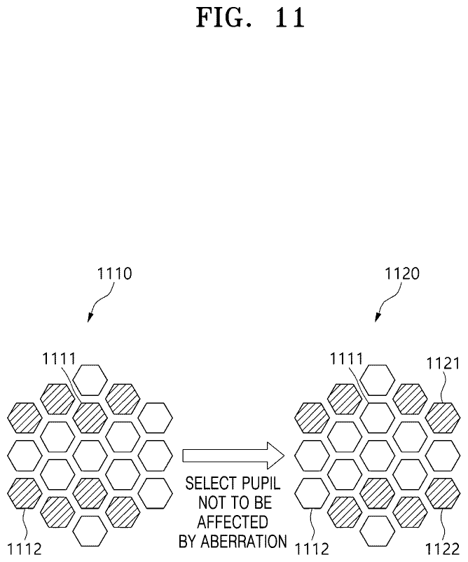

Also, the rendering tool 521 may detect an aberration area where aberration of the equipment included in the EUV lithography device is greater than a threshold value. That is, the aberration of the equipment satisfies a defined threshold value. The rendering tool 521 may perform rendering of selecting a changed pupil facet to replace the aberration pupil facet corresponding to the aberration area, based on the position matching information, the target image, and the aberration. Hereinafter, a rendering method of selecting a changed pupil facet to replace an aberration pupil facet will be described in detail with reference to FIGS. 10 and 11.

The input/output device 530 may be implemented to control a user input/output from a user interface device. For example, the input/output device 530 may include input means, such as a keyboard, a keypad, a mouse, and a touch screen to receive information from a designer. The designer may receive information about data paths or semiconductor areas requiring adjusted operation characteristics by using the input/output device 530. Also, the input/output device 530 may include output means such as a printer and a display to display a processing process and results of the rendering tool 521.

The storage device 540 may be provided as a storage medium of the computing device 500. The storage device 540 may store application programs, an OS image, and various data. The storage device 540 may be provided as a large-capacity storage device, such as a memory card (e.g., MMC, eMMC, SD, or Micro SD), a hard disk drive (HDD), a solid state drive (SSD), or a universal flash storage (UFS).

FIG. 7 is a diagram for describing a rendering method considering deterioration of an EUV lithography device, according to an embodiment. The description made with reference to FIGS. 1 to 6 may also apply to FIG. 7.

Referring to FIG. 7, because a rendering tool (e.g., the rendering tool 521) according to an embodiment may select desired active pupil facets, when deterioration occurs in a specific pupil facet due to contamination or deterioration of equipment, another pupil facet instead of the specific pupil facet may be selected to improve wafer image quality.

Referring to a first image 710, the rendering tool may obtain pupil intensity information of active pupil facets 711 and 716, and may detect a deteriorated pupil facet 711 whose pupil intensity has fallen below a threshold value. Referring to a second image 720, the rendering tool may change a pupil shape by selecting a changed pupil facet 721 instead of the deteriorated pupil facet 711. As the changed pupil facet 721 is selected instead of the deteriorated pupil facet 711, a contamination or deterioration status of equipment may be reflected when determining a pupil shape, thereby improving an NILS.

However, when a pupil shape is too different from a target image due to the selection of the changed pupil facet 721, the pupil shape may deviate from an ideal pupil shape and thus wafer pattern quality may be lowered. Accordingly, the rendering tool may replace a deteriorated pupil facet with a changed pupil facet only when it is determined that first performance degradation that may occur due to the deteriorated pupil facet (e.g., the deteriorated pupil facet 711) is greater than second performance degradation that may occur by selecting the changed pupil facet (e.g., the changed pupil facet 721).

In more detail, the rendering tool may determine candidate pupil facets to be selected instead of the deteriorated pupil facet 711 from among inactive pupil facets, based on position matching information and a pupil intensity. The inactive pupil facets may be pupil facets excluding the active pupil facets 711 to 716 from among pupil facets included in a PFM. The rendering tool may determine inactive pupil facets whose distance to the deteriorated pupil facet 711 is less than a threshold value from among the inactive pupil facets as candidate pupil facets 721 to 725. A method of determining a candidate pupil facet is not limited to the above example. For example, the rendering tool may determine all of the inactive pupil facets as candidate pupil facets.

The rendering tool may perform preliminary rendering by replacing the deteriorated pupil facet 711 with each of the candidate pupil facets 721 to 725. The rendering tool may obtain a preliminary rendering score as a result of performing preliminary rendering corresponding to each of the candidate pupil facets 721 to 725, based on the target image. The rendering tool may select the changed pupil facet 721 to replace the deteriorated pupil facet 711 from among the candidate pupil facets 721 to 725, based on the preliminary rendering score.

In more detail, the rendering tool may compare each result of performing preliminary rendering corresponding to each of the candidate pupil facets 721 to 725 with the target image, and may obtain a preliminary rendering score based on a comparison result. For example, the preliminary rendering score may be proportional to a similarity between the result of performing preliminary rendering and the target image. The rendering tool may determine a candidate pupil facet having a highest preliminary rendering score from among the candidate pupil facets 721 to 725, and when the preliminary rendering score of the candidate pupil facet having the highest preliminary rendering score is equal to or greater than a threshold value, i.e., the preliminary rendering score satisfies the threshold value, the rendering tool may select the candidate pupil facet as the changed pupil facet 721. When the preliminary rendering score of the candidate pupil facet having the highest preliminary rendering score is less than the threshold value, i.e., the preliminary rendering score does not satisfy the threshold value, the rendering tool may not replace the deteriorated pupil facet 711 with the changed pupil facet 721. The threshold value may be a point at which first performance degradation and second performance degradation described above are the same.

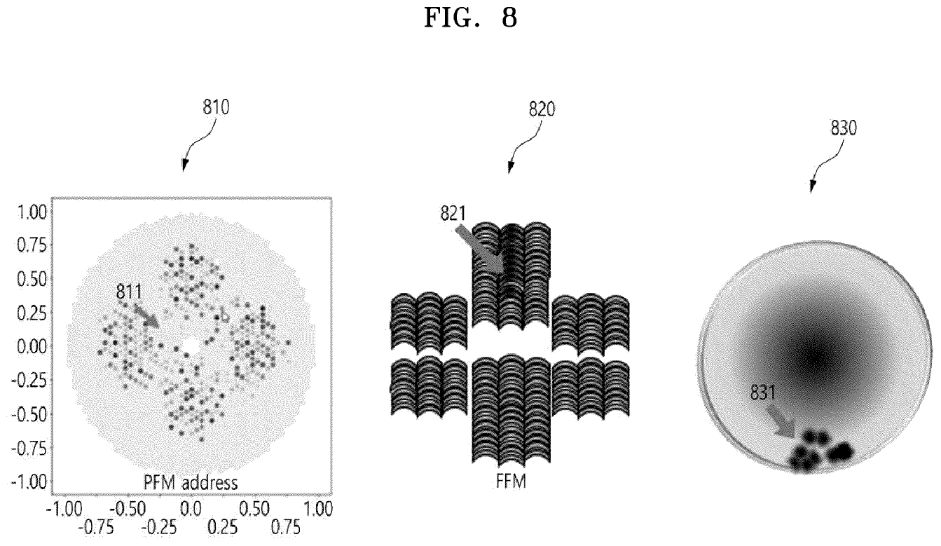

FIG. 8 is a diagram for describing a method of determining whether equipment included in an EUV lithography device has deteriorated based on a pupil intensity, according to an embodiment. The description made with reference to FIGS. 1 to 7 may also apply to FIG. 8.

Referring to FIG. 8, a rendering tool (e.g., the rendering tool 521) according to an embodiment may determine whether equipment included in an EUV lithography device deteriorates based on a pupil intensity. In more detail, the rendering tool may obtain position information of a deteriorated pupil facet 811 whose pupil intensity is less than a threshold value in a PFM 810. Because the rendering tool knows position matching information between an FFM and the PFM, the rendering tool may detect a position of a field facet 821 corresponding to the deteriorated pupil facet 811 in an FFM 820. The rendering tool may provide position information of the field facet 821 to a user so that the user may check whether the field facet 821 is contaminated. Furthermore, the rendering tool may detect a position of a contamination area 831 corresponding to the deteriorated pupil facet 811 in a collector 830. The rendering tool may provide position information of the contamination area 831 of the collector 830 to the user so that the user may check whether the collector 830 is contaminated.

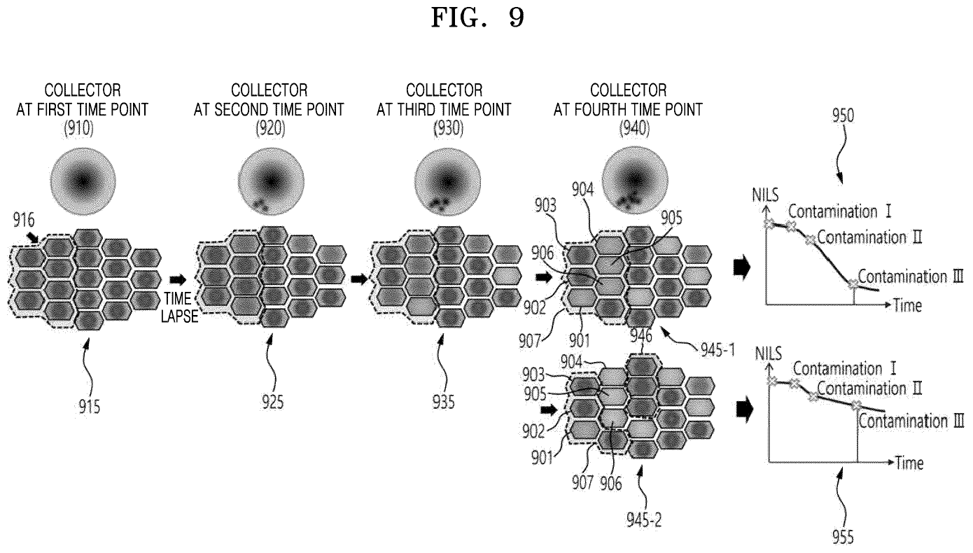

FIG. 9 is a diagram illustrating an example of reflecting a contamination status of a collector when determining a pupil shape, according to an embodiment. The description made with reference to FIGS. 1 to 8 may also apply to FIG. 9.

Referring to FIG. 9, because a collector 910 at a first time point is a collector immediately after replacement and is free of contamination, there may be no deteriorated pupil facet in active pupil facets 916 of a PFM 915 at the first time point.

Although a collector 920 at a second time point and a collector 930 at a third time point are contaminated over time, there may not be yet a pupil facet whose pupil intensity has fallen below a threshold value in the active pupil facets 916 of a PFM 925 at the second time point and a PFM 935 at the third time point.

A collector 940 at a fourth time point may be severely contaminated, and thus, there may be deteriorated pupil facets 901, 904, 905, and 906 whose pupil intensity has fallen below the threshold value in a PFM 945-1 at the fourth time point.

A rendering tool (e.g., the rendering tool 521 of FIG. 5) may perform rendering of selecting a changed pupil facet to replace a deteriorated pupil facet, based on position matching information, a target image, and a pupil intensity. For example, referring to a PFM 945-2 after rendering, the rendering tool may change three deteriorated pupil facets 904, 905, and 906 from among the deteriorated pupil facets 904, 904, 905, and 906 with changed pupil facets 946. However, the rendering tool may determine that when the deteriorated pupil facet 901 is replaced with another pupil facet, wafer pattern quality may be lowered. Accordingly, the rendering tool may not replace the deteriorated pupil facet 901 with another pupil facet.

An NILS refers to a slope of an image profile, and as an NILS value increases, a pattern boundary becomes clearer, and as an NILS value decreases, a pattern boundary becomes more blurred, thereby lowering resolution. Comparing an NILS graph 950 measured based on the PFM 925 at the fourth time point with an NILS graph 955 measured based on the PFM 945-2 after rendering, it may be found that NILS reduction is reduced through rendering.

FIGS. 10 to 12 are diagrams for describing a rendering method considering aberration of equipment, according to an embodiment. The description made with reference to FIGS. 1 to 9 may also apply to FIGS. 10 to 12.

Referring to FIG. 10, referring to a color map 1010 for a phase change of an xx component J_{XX} of a Jones matrix of first equipment, a color map 1020 for a phase change of an xx component J_{XX} of a Jones matrix of second equipment, and a color map 1030 for a phase change of an xx component J_{XX} of a Jones matrix of third equipment, it may be found that an area with large aberration varies according to a type of equipment. The first equipment, the second equipment, and the third equipment may be the same type of equipment, or may be similar types of equipment operated under different conditions or settings. For example, the first equipment, the second equipment, and the third equipment may be different types of equipment. In other embodiments, the first equipment, the second equipment, and the third equipment may be the same equipment (e.g., projection optical system) but may refer to results measured in different states over time. As described above, aberration of mirrors included in a projection optical system may be measured through a measurement device, such as a wavefront sensor or an interferometer, and an area whose aberration is greater than a threshold value may be defined as an aberration area. Because an aberration area may vary according to equipment, to form a more accurate pupil shape, an aberration area of corresponding equipment may be detected and a PFM should be rendered by considering the aberration area.

Referring to FIG. 11, a rendering tool may obtain aberration information of equipment included in an EUV lithography device, and may perform rendering of a PFM based on position matching information, a target image, and aberration.

Referring to a first image 1110, the rendering tool may detect aberration pupil facets 1111 and 1112 corresponding to an aberration area. The rendering tool may obtain wavefront information of light output from the equipment included in the EUV lithography device, and may calculate a Zernike coefficient based on the wavefront information. The Zernike coefficient may be a value that mathematically represents optical aberration. The rendering tool may determine an aberration area where aberration of the equipment is greater than a threshold value based on the Zernike coefficient, and may detect the aberration pupil facets 1111 and 1112 corresponding to the aberration area. Referring to a second image 1120, the rendering tool may change a pupil shape by selecting changed pupil facets 1121 and 1122 instead of the aberration pupil facets 1111 and 1112. Because the changed pupil facets 1121 and 1122 are selected instead of the aberration pupil facets 1111 and 1112, aberration of the equipment may be reflected when determining a pupil shape, thereby improving an NILS.

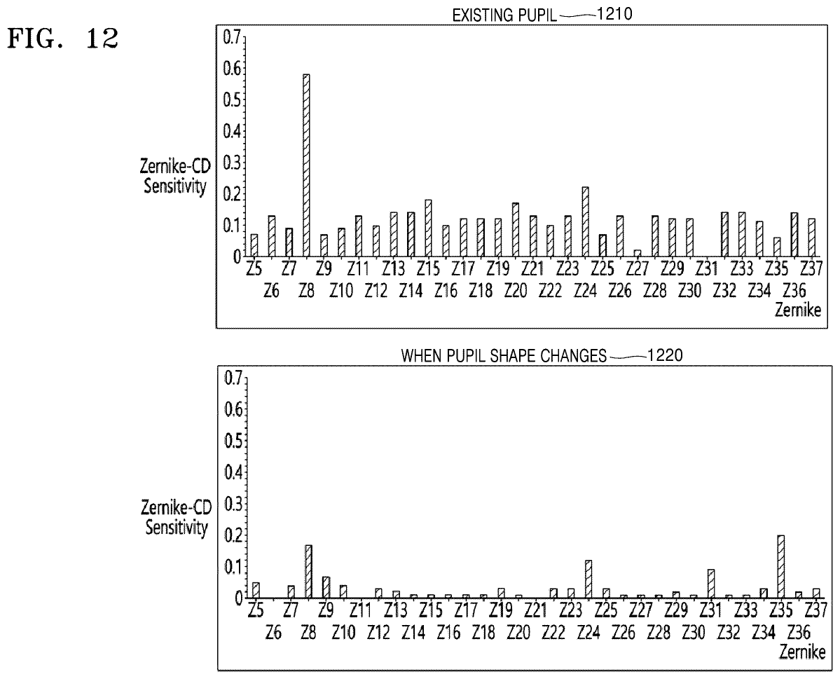

Referring to FIG. 12, a first graph may be a Zernike-CD sensitivity graph before aberration is considered, and a second graph 1220 may be a Zernike-CD sensitivity graph when rendering is performed considering aberration. An x-axis of the Zernike-CD sensitivity graph may represent a Zernike coefficient, and a y-axis may represent a Zernike-CD sensitivity indicating the effect of a Zernike coefficient on a CD of a semiconductor device. As a Zernike-CD sensitivity increases, it may mean that corresponding aberration has a greater effect on a CD, and a CD change is greater when there is the corresponding aberration.

Comparing the first graph 1210 with the second graph 1220, it may be found that a Zernike-CD sensitivity is low when rendering is performed considering aberration, and thus, aberration when rendering is performed considering aberration does not significantly affect a CD.

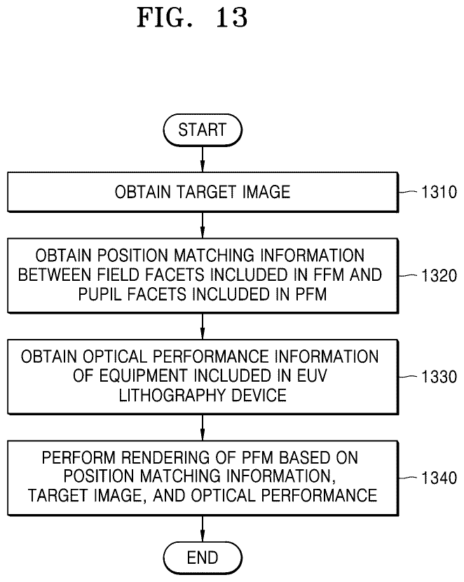

FIG. 13 is a flowchart for describing an operating method of an EUV lithography device, according to an embodiment. The description made with reference to FIGS. 1 to 12 may also apply to FIG. 13. Operations 1310 to 1340 are performed by using the rendering tool 521 of FIG. 5. However, it will be understood that operations 1310 to 1340 may be used through any other appropriate electronic device and within any appropriate system.

Furthermore, the operations of FIG. 13 may be performed in the order and manner illustrated in FIG. 13, but the order of some operations may be changed or some operations may be omitted without departing from the spirit and scope of the inventive concept. A plurality of operations illustrated in FIG. 13 may be performed in parallel or simultaneously.

In operation 1310, a rendering tool according to an embodiment may obtain a target image.

In operation 1320, the rendering tool according to an embodiment may obtain position matching information between field facets included in an FFM and pupil facets included in a PFM. The rendering tool may obtain a light path when light output from the FFM reaches the PFM.

In operation 1330, the rendering tool according to an embodiment may obtain optical performance information of equipment included in an EUV lithography device. The optical performance information may include at least one of a pupil intensity of the pupil facets included in the PFM and aberration of the equipment included in the EUV lithography device.

In operation 1340, the rendering tool according to an embodiment may perform rendering of the PFM based on the position matching information, the target image, and optical performance.

The rendering tool may perform first rendering of selecting active pupil facets corresponding to the target image, based on the position matching information.

The rendering tool may detect a deteriorated pupil facet whose pupil intensity is less than a threshold value from among the active pupil facets, and may perform second rendering of selecting a changed pupil facet to replace the deteriorated pupil facet based on the position matching information, the target image, and the pupil intensity.

The rendering tool may determine candidate pupil facets to be selected instead of the deteriorated pupil facet from among inactive pupil facets excluding the active pupil facets from among the pupil facets included in the PFM based on the position matching information and the pupil intensity, and may determine a changed pupil facet to replace the deteriorated pupil facet from among the candidate pupil facets based on the target image and the pupil intensity.

The rendering tool may perform preliminary rendering by replacing the deteriorated pupil facet with each of the candidate pupil facets, may obtain a preliminary rendering score of a result of performing preliminary rendering corresponding to each of the candidate pupil facets based on the target image, and may determine a changed pupil facet based on the preliminary rendering score.

The rendering tool may determine candidate pupil facet facets to be selected instead of the deteriorated pupil facet from among inactive pupil facets excluding the active pupil facets from among the pupil facets included in the PFM based on the position matching information and the pupil intensity, and may determine a changed pupil facet to replace the deteriorated pupil facet from among the candidate pupil facets based on the target image and the pupil intensity.

The rendering tool may perform preliminary rendering by replacing the deteriorated pupil facet with each of the candidate pupil facets, may obtain a preliminary rendering score of a result of performing preliminary rendering corresponding to each of the candidate pupil facets based on the target image, and may determine a changed pupil facet based on the preliminary rendering score.

The rendering tool may compare a result of performing preliminary rendering corresponding to each of the candidate pupil facets with the target image, and may obtain a preliminary rendering score based on a comparison result.

The rendering tool may determine a candidate pupil facet having a highest preliminary rendering score from among the candidate pupil facets, and when the preliminary rendering score of the candidate pupil facet having the highest preliminary rendering score is equal to or greater than a threshold value, may determine the candidate pupil facet as a changed pupil facet.

The rendering tool may determine whether the equipment included in the EUV lithography device deteriorates based on the pupil intensity.

The rendering tool may determine whether the field facets included in the FFM deteriorate based on the pupil intensity, and may determine whether a collector included in the EUV lithography device deteriorates based on the pupil intensity and whether the field facets deteriorate.

The rendering tool may obtain the target image by using a source mask optimization (SMO) method.

The rendering tool may obtain aberration information of a projection optical system included in the EUV lithography device.

The rendering tool may obtain wavefront information of light output from the equipment included in the EUV lithography device, and may calculate a Zernike coefficient based on the wavefront information.

The rendering tool may detect an aberration area where aberration of the equipment included in the EUV lithography device is greater than a threshold value, and may perform a second rendering of selecting a changed pupil facet to replace an aberration pupil facet corresponding to the aberration area based on the position matching information, the target image, and the aberration.

The rendering tool may detect an aberration area where aberration of the equipment included in the EUV lithography device is greater than a threshold value, and may perform second rendering of selecting a changed pupil facet to replace an aberration pupil facet corresponding to the aberration area based on the position matching information, the target image, and the aberration.

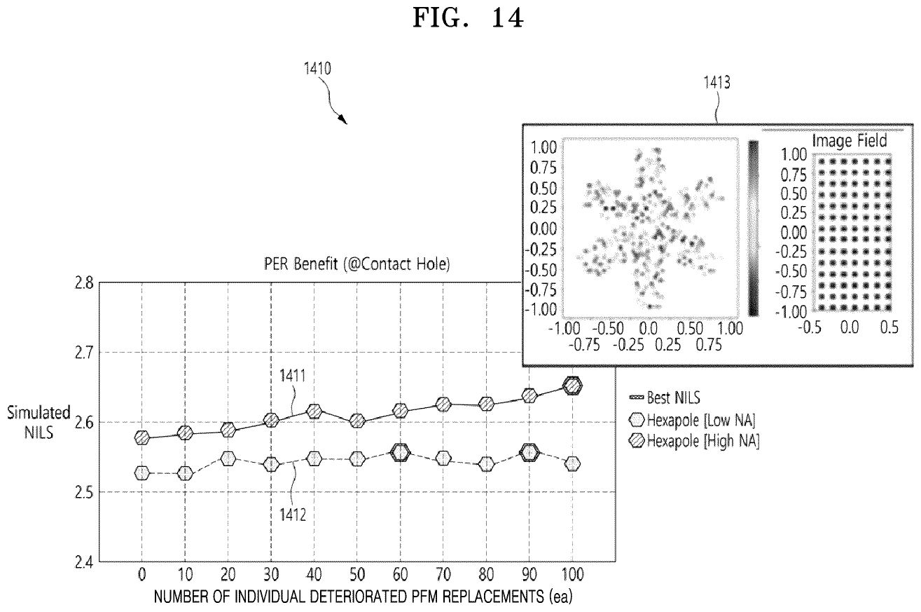

FIG. 14 is a graph illustrating an NILS change according to the number of pupil facet replacements of a PFM, according to an embodiment.

Referring to FIG. 14, an x-axis of a graph 1410 represents the number of deteriorated pupil facets replaced with changed pupil facets included in a PFM, and a y-axis represents a simulated NILS obtained through simulation. A first curve 1411 shows an NILS measured under a low numerical aperture (NA) and a hexapole pattern 1413, and a second curve 1412 shows an NILS measured under a high NA and the hexapole pattern 1413. When the first curve 1411 and the second curve 1412 are compared with each other, it may be found that greater image quality improvement is shown at a higher NA than at a lower NA. In other words, the effect of a rendering method according to an embodiment may increase as an NA increases.

Various embodiments and the terms used herein are not intended to limit the technological features set forth herein to particular embodiments and include various changes, equivalents, or replacements for a corresponding embodiment. In relation to the description of drawings, similar or related reference numerals may denote similar elements. A singular form of a noun corresponding to an item may include one or more items, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Such terms as “1st” and “2nd,” or “first” and “second” may be used to simply distinguish a corresponding component from another, and does not limit the components in another aspect (e.g., importance or order). When an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wired), wirelessly, or via a third element.

According to an embodiment, methods according to various embodiments may be provided in a computer program product. The computer program product may be a product purchasable between a seller and a purchaser. The computer program product may be distributed in the form of a non-transitory machine-readable storage medium (e.g., a compact disc read-only memory (CD-ROM)), or distributed (e.g., downloaded or uploaded) online via an application store (e.g., Play Store™) or between two user devices (e.g., smartphones) directly. In the case of online distribution, at least a part of the computer program product may be temporarily stored or temporarily generated in the non-transitory machine-readable storage medium such as a memory of a server of a manufacturer, a server of an application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, the integrated component may perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

The effects obtainable in the inventive concept are not limited to the above effects, and other effects not mentioned may be clearly understood by one of ordinary skill in the art from the specification.

While the inventive concept has been particularly shown and described with reference to embodiments thereof, it will be understood that various changes in form and details may be made therein without departing from the spirit and scope of the following claims.

What is claimed is:

1. An operating method of an extreme ultraviolet (EUV) lithography device, the operating method comprising:
obtaining a target image;
obtaining position matching information between field facets included in a field facet mirror (FFM) and pupil facets included in a pupil facet mirror (PFM);
obtaining information of a pupil intensity of the pupil facets of the PFM; and
performing rendering of one or more individually selectable pupil facets of the PFM based on the position matching information, the target image, and the pupil intensity.

2. The operating method of claim 1, wherein the performing of the rendering comprises performing a first rendering comprising selecting active pupil facets corresponding to the target image, based on the position matching information.

3. The operating method of claim 2, further comprising:
detecting a deteriorated pupil facet whose pupil intensity is less than a threshold value from among the active pupil facets; and
performing a second rendering comprising selecting a changed pupil facet to replace the deteriorated pupil facet, based on the position matching information, the target image, and the pupil intensity.

4. The operating method of claim 3, wherein the performing of the second rendering comprises:
determining candidate pupil facets to be selected for replacement of the deteriorated pupil facet from among inactive pupil facets excluding the active pupil facets from among the pupil facets included in the PFM, based on the position matching information and the pupil intensity; and
selecting the changed pupil facet as a replacement for the deteriorated pupil facet from among the candidate pupil facets, based on the target image and the pupil intensity.

5. The operating method of claim 4, wherein the determining of the changed pupil facet comprises:
performing a preliminary rendering by replacing the deteriorated pupil facet with each of the candidate pupil facets;
obtaining a preliminary rendering score of a result of performing the preliminary rendering corresponding to each of the candidate pupil facets, based on the target image; and
selecting the changed pupil facet, based on the preliminary rendering score.

6. The operating method of claim 5, wherein the obtaining of the preliminary rendering score comprises:
comparing the result of performing the preliminary rendering corresponding to each of the candidate pupil facets with the target image; and
obtaining the preliminary rendering score, based on a result of the comparing.

7. The operating method of claim 5, wherein the selecting of the changed pupil facet comprises:
determining a candidate pupil facet having a highest preliminary rendering score from among the candidate pupil facets; and
when the preliminary rendering score of the candidate pupil facet having the highest preliminary rendering score is equal to or greater than a threshold value, selecting the candidate pupil facet as the changed pupil facet.

8. The operating method of claim 1, wherein the rendering comprises a first rendering and wherein the performing of the first rendering comprises:
determining a deteriorated pupil facet whose pupil intensity is less than a threshold value from among the pupil facets included in the PFM; and
performing a second rendering of changing a position of the deteriorated pupil facet, based on the position matching information, the target image, and the pupil intensity.

9. The operating method of claim 1, further comprising determining whether equipment included in the EUV lithography device is in a deteriorated state based on the pupil intensity.

10. The operating method of claim 1, further comprising:
determining whether the field facets included in the FFM have deteriorated, based on the pupil intensity; and
determining whether a collector included in the EUV lithography device has deteriorated, based on the pupil intensity and whether the field facets have deteriorated.

11. The operating method of claim 1, wherein the obtaining of the target image comprises obtaining the target image by using a source mask optimization (SMO) method.

12. An operating method of an extreme ultraviolet (EUV) lithography device, the operating method comprising:
obtaining a target image;
obtaining position matching information between field facets included in a field facet mirror (FFM) and pupil facets included in a pupil facet mirror (PFM);
obtaining aberration information of equipment included in the EUV lithography device; and
performing rendering of the PFM based on the position information, the target image, and the aberration information.

13. The operating method of claim 12, wherein the obtaining of the aberration information comprises obtaining aberration information of a projection optical system included in the EUV lithography device.

14. The operating method of claim 12, wherein the obtaining of the aberration information comprises:
obtaining wavefront information of light emitted from the equipment included in the EUV lithography device; and
calculating a Zernike coefficient based on the wavefront information.

15. The operating method of claim 12, wherein the performing of the rendering comprises performing a first rendering comprising selecting active pupil facets corresponding to the target image, based on the position matching information.

16. The operating method of claim 15, wherein the performing of the rendering comprises:
detecting an aberration area where an aberration of the equipment included in the EUV lithography device is greater than a threshold value;
performing a second rendering comprising selecting a changed pupil facet to replace an aberration pupil facet corresponding to the aberration area, based on the position matching information, the target image, and the aberration.

17. The operating method of claim 12, wherein the rendering comprise a first rendering and wherein the performing of the first rendering comprises:
detecting an aberration area where an aberration of the equipment included in the EUV lithography device is greater than a threshold value; and
performing a second rendering comprising selecting a changed pupil facet to replace an aberration pupil facet corresponding to the aberration area, based on the position matching information, the target image, and the aberration.

18. An operating method of an extreme ultraviolet (EUV) lithography device, the operating method comprising:
obtaining a target image;
obtaining light path information for light output from a field facet mirror (FFM) reaching a pupil facet mirror (PFM);
obtaining optical performance information of equipment included in the EUV lithography device; and
performing rendering of the PFM corresponding to the target image based on the light path information, the target image, and the optical performance information.

19. The operating method of claim 18, wherein the optical performance information comprises at least one of a pupil intensity of pupil facets included in the PFM and aberration of the equipment included in the EUV lithography device.

20. The operating method of claim 19, wherein the obtaining of the aberration information comprises obtaining aberration information of a projection optical system included in the EUV lithography device;
obtaining wavefront information of light emitted from the equipment included in the EUV lithography device; and
calculating a Zernike coefficient based on the wavefront information.
